(19) United States
(12) Patent Application Publication
(10) Pub. No.: US 2026/0347660 A1
(43) Pub. Date: Nov. 5, 2026

(54) CATIONIC COLLOIDAL SILICA RATIO CMP COMPOSITION

(71) Applicant: ENTEGRIS, INC., Billerica, MA (US)

(72) Inventors: Tamil Sakthivel, Aurora, IL (US); Steven Grumbine, Aurora, IL (US)

(21) Appl. No.: 19/658,070

(22) Filed: Apr. 24, 2026

Related U.S. Application Data
(60) Provisional application No. 63/794,045, filed on Apr. 24, 2025.

(51) Int. Cl. C09G 1/02; B24B 37/04; C09K 3/14; H10P 52/40

(52) U.S. Cl. CPC C09G 1/02; B24B 37/044; C09K 3/1436; H10P 52/403; H10P 52/407

(57) ABSTRACT

A chemical mechanical polishing composition comprises, consists of, or consists essentially of a liquid carrier, colloidal silica particles dispersed in the liquid carrier, an aminosilane compound covalently bonded to an outer surface of the colloidal silica particles such that the colloidal silica particles have a positive charge in the polishing composition, and a nonionic silane compound covalently bonded to the outer surface of the colloidal silica particles, wherein a molar ratio of the nonionic silane compound to the aminosilane compound bonded to the surface of the colloidal silica particles is greater than about 4:1.

### CROSS REFERENCE TO RELATED APPLICATIONS

This application claims the benefit of U.S. Provisional Application Ser. No. 63/794,045, entitled Cationic Colloidal Silica Ratio CMP Composition, filed Apr. 24, 2025, which is incorporated herein by reference in its entirety.

### BACKGROUND OF THE INVENTION

Chemical mechanical polishing (CMP) compositions and methods for polishing (or planarizing) the surface of a substrate are well known. Polishing compositions (also known as polishing slurries, CMP slurries, and CMP compositions) for polishing various metal (such as tungsten) and non-metal (such as silicon oxide) layers on a semiconductor substrate may include abrasive particles suspended in an aqueous solution and various chemical additives such as oxidizers, chelating agents, catalysts, topography control agents, buffers, and the like.

In a conventional CMP operation, the substrate (wafer) to be polished is mounted on a carrier which is in turn mounted on a carrier assembly and positioned in contact with a polishing pad in a CMP polishing tool. The carrier assembly provides a controlled pressure to the substrate against the polishing pad. The substrate and pad are moved relative to one another by an external driving force. The relative motion of the substrate and pad abrades and removes a portion of the material from the surface of the substrate, thereby polishing the substrate. The polishing of the substrate by the relative movement of the pad and the substrate may be further aided by the chemical activity of the polishing composition and/or the mechanical activity of an abrasive suspended in the polishing composition.

In many CMP operations achieving optimum planarization and/or planarization efficiency is of critical importance. For example, in tungsten CMP operations excessive oxide erosion and/or dishing may lead to difficulties in subsequent lithography steps as well as cause electrical contact problems that can degrade electrical performance. Achieving such optimum planarization with a minimum of defects may also be of critical importance as polishing defects are known to negatively impact electrical performance. Despite many advances to commercial CMP slurries, there remains a need in the industry for CMP slurries (or compositions), such as tungsten CMP slurries, that provide for improved planarity and reduced defects during a CMP operation.

### BRIEF SUMMARY OF THE INVENTION

A chemical mechanical polishing composition is disclosed. The composition comprises, consists of, or consists essentially of a liquid carrier, colloidal silica particles dispersed in the liquid carrier, an aminosilane compound covalently bonded to an outer surface of the colloidal silica particles such that the colloidal silica particles have a positive charge in the polishing composition, and a nonionic silane compound covalently bonded to the outer surface of the colloidal silica particles, wherein a molar ratio of the nonionic silane compound to the aminosilane compound bonded to the surface of the colloidal silica particles is greater than about 4:1.

### DETAILED DESCRIPTION OF THE INVENTION

Chemical mechanical polishing compositions and methods for using those compositions to polish a substrate are disclosed. In one example embodiment, a chemical mechanical polishing composition comprises, consists essentially of, or consists of an aqueous based liquid carrier, colloidal silica particles dispersed in the liquid carrier, an aminosilane compound covalently bonded to an outer surface of the colloidal silica particles such that the colloidal silica particles have a positive charge in the polishing composition, and a nonionic silane compound covalently bonded to the outer surface of the colloidal silica particles, wherein a molar ratio of the nonionic silane compound to the aminosilane compound bonded to the surface of the colloidal silica particles is greater than about 4:1. The pH of the composition may be less than 5 when used for tungsten or molybdenum CMP applications. Methods for polishing metals or dielectric layers (e.g., tungsten, molybdenum, or carbon) in a substrate include contacting the substrate with the polishing composition, moving the polishing composition relative to the substrate, and abrading the substrate to remove a portion of the layer from the substrate and thereby polish the substrate.

Example polishing compositions include dual silane modified colloidal silica particles suspended (dispersed) in a liquid carrier. As used herein the term dual silane modified colloidal silica particles refers to colloidal silica particles that are modified with (e.g., covalently bonded with) at least first and second silicon containing molecules or compounds. In example embodiments, the colloidal silica particles may be modified with a first silane compound including an aminosilane such that the colloidal silica particles have a positive charge in the polishing composition and a second nonionic, hydrophobic silane compound. It has been found that example embodiments of the disclosed polishing compositions including dual silane treated colloidal silica particles as described herein advantageously achieve improved patterned wafer performance and particularly improved erosion performance as compared to polishing compositions including conventional colloidal silica particles (that are not dual silane modified).

The dual silane modified colloidal silica particles may include substantially any suitable colloidal silica particles. In other words, substantially any suitable colloidal silica particles may be modified with the first and second silicon containing compounds and used in the disclosed polishing compositions. In preferred embodiments, the colloidal silica particles are nonporous. As used herein the term colloidal silica particles refers to silica particles that are prepared via a wet process rather than a pyrogenic or flame hydrolysis process which produces structurally different particles. The colloidal silica may be precipitated or condensation-polymerized silica, which may be prepared using any method known to those of ordinary skill in the art, such as by the sol gel method or by silicate ion-exchange. Condensation-polymerized silica particles are often prepared by condensing Si(OH)₄ to form substantially spherical particles.

The dual silane modified colloidal silica particles may have substantially any suitable average particle size as measured using a CPS Disc Centrifuge Particle size analyzer (e.g., Model DC24000 HR available from CPS Instruments, Prairieville, Louisiana). Note that as used herein the average particle size is taken to be the D50 of the measured distribution. In example embodiments, the dual silane modified colloidal silica particles may have an average particle size in a range from about 5 nm to about 300 nm (e.g., from about 10 nm to about 250 nm, from about 20 nm to about 200 nm, from about 25 nm to about 200 nm, from about 40 nm to about 200 nm, or from about 40 nm to about 160 nm).

The dual silane modified colloidal silica particles may have substantially any suitable surface area. For example, the dual silane modified colloidal silica particles may further be characterized as having a BET surface area in a range from about 20 m²/g to about 200 m²/g (e.g., in a range from about 30 m²/g to about 180 m²/g, from about 40 m²/g to about 160 m²/g, or from about 50 m²/g to about 150 m²/g). The BET surface area may be measured, for example, as described in Colloids and Surfaces A: Physicochem. Eng. Aspects 322 (2008) 248-252.

The dual silane modified colloidal silica particles may have substantially any suitable aspect ratio. The aspect ratio of a colloidal silica particle is defined herein as the maximum caliper diameter of the particle divided by the minimum caliper diameter of the particle (hence the aspect ratio is always greater than or equal to 1). For example, the dual silane modified colloidal silica particles may further be characterized as having a number average aspect ratio in a range from about 1 to about 2 (e.g., from about 1 to about 1.8, from about 1 to about 1.6, or from about 1.1 to about 1.5). The number average aspect ratio represents a statistical measure of the average (median) aspect ratio of the colloidal silica particles in the polishing composition (on a number rather than a weight basis). The number average aspect ratio may be referred to as AR50 since statistically half (50%) of the particles have an aspect ratio less than the median value and half (50%) of the particles have an aspect ratio greater than the median value.

The number average aspect ratio of the colloidal silica particles in a polishing composition may be determined by evaluating a large number of particles in high magnification transmission electron microscopy (TEM) images (e.g., at a magnification in a range from about 10,000 to about 30,000). To obtain a statistically significant median aspect ratio it is generally necessary to measure and compute the aspect ratio for a large number of colloidal silica particles (e.g., at least 500 or more particles or even 1000 or more particles) using a plurality of images (e.g., at least 10 or more images, 15 or more images, or even 20 or more images). The maximum caliper diameter and the minimum caliper diameter of each of the particles may be measured manually (particle by particle), for example, using the scale bar on the TEM image. However, a user-guided automated process is practically preferred based upon the requirement to evaluate a large number of particles. Such automated processes preferably make use of commercially available image analysis software.

The dual silane modified colloidal silica particles may have substantially any suitable degree of aggregation. In other words, the dual silane modified colloidal silica particles may be aggregated, partially aggregated, and/or non-aggregated. For example, in some embodiments, a portion of the particles may be aggregated and the remainder may be non-aggregated. Non-aggregated particles are individually discrete particles (commonly referred to in the art as primary particles or primaries) that are generally spherical or nearly spherical in shape. Aggregated particles are particles in which multiple primary particles are clustered or bonded together to form aggregates having generally irregular or non-spherical shapes (such as elongated or branched). Non-aggregated (primary) particles may also be referred to herein as monomers. Aggregated particles may also be referred to as dimers (having two primaries), trimers (having three primaries), tetramers (having four primaries), and so on.

In example embodiments, the dual silane modified colloidal silica particles may be substantially non-aggregated in that they include mostly primary particles. In other embodiments, the dual silane modified colloidal silica particles may be partially aggregated. By partially aggregated it may be meant that 50 percent or more of the dual silane modified colloidal silica particles include two or more aggregated primary particles or that 30 percent or more (or 45 percent or more) of the colloidal silica particles include three or more aggregated primary particles. In still other embodiments, the dual silane modified colloidal silica particles may have an aggregate distribution in which 20 percent or more of the dual silane modified colloidal silica particles include less than three primary particles (i.e., non-aggregated primary particles or aggregated particles having just two primary particles, also referred to as monomers and dimers) and 50 percent or more of the dual silane modified colloidal silica particles include three or more aggregated primary particles.

Partially aggregated colloidal silica particles may be prepared, for example, using a multi-step process in which primary particles are first grown in solution, for example as described in U.S. Pat. No. 5,230,833. The pH of the solution may then be adjusted to an acidic value for a predetermined time period to promote aggregation (or partial aggregation), for example, as described in U.S. Pat. No. 8,529,787. An optional final step may allow for further growth of the aggregates (and any remaining primary particles).

In example embodiments, the polishing composition may include a mixture of at least first and second colloidal silica particles. The mixture may include, for example, a mixture of first dual silane modified colloidal silica particles and second colloidal silica particles that may or may not be dual silane modified. In some example embodiments, both the first and second colloidal silica particles may be dual modified colloidal silica particles. In example embodiments including first and second colloidal silica particles, the first dual silane modified colloidal silica particles may be characterized as having an aspect ratio of less than about 1.25 (e.g., less than about 1.2 or less than about 1.15) and the second colloidal silica particles may have an aspect ratio of greater than about 1.25 (e.g., greater than about 1.3 or greater than about 1.35). Moreover, in such embodiments, the first dual silane modified colloidal silica particles may have a particle size that is greater than about 80 nm (e.g., greater than about 90 nm or greater than about 100 nm) and the second colloidal silica particles may have a particle size in a range from about 30 nm to about 80 nm (e.g., from about 30 to about 60). In other example embodiments, the first colloidal silica particles may have a particle size that is greater than about 80 nm and may be dual silane modified and the second colloidal silica particles may have a particle size that is less than about 50 nm (e.g., less than 30 nm) and may not be dual silane modified (or may be dual silane modified with a lower modification level than the first colloidal silica particles).

The dual silane modified colloidal silica particles may advantageously have a high purity. For example, the dual silane modified colloidal silica particles may have a total metals impurity (in which the metals include sodium, aluminum, calcium, magnesium, and the transition metals) of less than 20 parts per million (e.g., less than 15 ppm, less than 10 ppm, less than 5 ppm, less than 2.5 ppm, or less than 1 ppm). In such embodiments, the particles may be potassium or ammonia stabilized. The silica (e.g., colloidal silica) may further have a total metals impurity (in which the metals include potassium, sodium, iron, aluminum, calcium, magnesium, titanium, nickel, chromium, copper, and zinc) of less than 20 parts per million (e.g., less than 15 ppm, less than 10 ppm, less than 5 ppm, less than 2.5 ppm, or less than 1 ppm). In such embodiments, the particles may be ammonia or amine stabilized.

In the disclosed embodiments, the colloidal silica particles may include substantially any suitable commercially available colloidal silicas. Those of ordinary skill in the art will readily appreciate that colloidal silicas having a wide range of physical properties are commercially available from a large number of vendors, for example, including Nissan Chemical Industries, Ltd., Nalco Holding Company, W.R. Grace and Company, Fuso Chemical Company, Nouryon, Nyacol Nano Technologies, Inc., Tama Chemicals Company, and JGC Holdings Corporation.

The disclosed polishing composition may include substantially any suitable amount of the dual silane modified colloidal silica particles. For example, the polishing composition may include about 0.01 wt. % or more dual silane modified colloidal silica particles at point of use (e.g., about 0.05 wt. % or more, about 0.1 wt. % or more, or about 0.2 wt. % or more). The amount of dual silane modified colloidal silica particles in the polishing composition may include about 5 wt. % or less at point of use (e.g., about 3 wt. % or less, about 2 wt. % or less, about 1.5 wt. % or less, or about 1 wt. % or less) Accordingly, the amount of dual silane modified colloidal silica particles may be in a range bounded by any two of the aforementioned endpoints, for example, in a range from about 0.01 wt. % to about 5 wt. % at point of use (e.g., from about 0.05 wt. % to about 5 wt. %, from about 0.1 wt. % to about 3 wt. %, from about 0.1 wt. % to about 2 wt. %, from about 0.01 wt. % to about 1 wt. %, or from about 0.2 wt. % to about 1 wt. %).

The dual silane modified colloidal silica particles may be modified (e.g., covalently bonded with) with first and second silicon containing compounds. In example embodiments, the first silicon containing compound includes a cationic group such that the dual silane modified colloidal silica particles have a positive charge in the polishing composition and the second silicon containing compound includes a nonionic group.

In example embodiments, the first silicon containing compound may include substantially any positively charged silicon containing compound that may covalently bond with the colloidal silica particles. The cationic group may include, for example, a nitrogen containing group, a sulfonium group, or a phosphonium group. In preferred embodiments, the cationic group includes a nitrogen containing group such as an amino group. In advantageous embodiments, the first silicon containing compound includes an aminosilane compound, for example, including primary aminosilanes, secondary aminosilanes, tertiary aminosilanes, quaternary aminosilanes, and/or multi-podal (e.g., dipodal) aminosilanes. In example embodiments, the aminosilane compound may include, for example, a propyl group containing aminosilane, or an aminosilane compound including a propyl amine. Examples of suitable classes of aminosilanes may include bis(2-hydroxyalkyl)-3-aminoalkyl trialkoxysilane, dialkylaminoalkyltrialkoxysilane (e.g., dialkylaminoalkoxysilane), (N,N-dialkyl-3-aminoalkyl) trialkoxysilane), 3-(N-styrylalkyl-2-aminoalkylaminoalkyl trialkoxysilane, aminoalkyl trialkoxysilane, (2-N-benzylaminoalkyl)-3-aminoalkyl trialkoxysilane), trialkoxysilyl alkyl-N,N,N-trialkyl ammonium, N-(trialkoxysilylalkyl)benzyl-N,N,N-trialkyl ammonium, (bis(alkyldialkoxysilylalkyl)-N-alkhyl amine, bis(trialkoxysilylalkyl) urea, bis(3-(trialkoxysilyl)alkyl)-ethylenediamine, bis(trialkoxysilylalkyl)amine, bis(trialkoxysilylalkyl)amine, 3-aminoalkyltrialkoxysilane, N-(2-aminoalkyl)-3-aminopropylmethyldialkoxysilane, N-(2-aminoalkyl)-3-aminoalkyltrialkoxysilane, 3-aminoalkylmethyldialkoxysilane, 3-aminoalkyltrialkoxysilane, (N-trialkoxysilylalkyl) polyethyleneimine, trialkoxysilylalkyl ethylenediamine, trialkoxysilylalkyl diethylenetriamine, N-phenyl-3-aminoalkyltrialkoxysilane, N-(vinylbenzyl)-2-aminoalkyl-3-aminoalkyltrialkoxysilane, 4-aminoalkyltrialkoxysilane, and mixtures thereof.

In preferred embodiments, the dual modified colloidal silica particles may be modified with a multi-podal (e.g., dipodal) aminosilane, such as bis(trialkoxysilyl) ethane, bis(trialkoxysilylalkyl)amine (e.g., bis(trimethoxysilylpropyl)amine or bis(triethoxysilylpropyl)amine), N-(hydroxyalkyl)-N,N-bis(trialkoxysilylalkyl)amine, N,N′-bis [(3-trialkoxysilyl)alkyl]ethylenediamine, N,N′-bis(2-hydroxyalkyl)-N,N′-bis(trialkoxysilylalkyl)ethylenediamine, tris(trialkoxysilylalkyl) amine, 1,11-bis(trialkoxysilyl)-4-oxa-8-azaundecan-6-ol, and mixtures thereof.

As noted above, the colloidal silica particles may be covalently bonded with multiple different aminosilane compounds. In certain preferred embodiments, the colloidal silica particles may be covalently bonded with a first mono-podal aminosilane compound and a second multi-podal aminosilane compound. While not wishing to be bound by theory, it is believed that a combination of a mono-podal aminosilane compound and a multi-podal aminosilane compound may enable a higher charge density to be attained. In example embodiments, the colloidal silica particles may be covalently bonded with a mono-podal aminosilane including 3-aminoalkyltrialkoxysilane, trialkoxysilylalkyl ethylenediamine, trialkoxysilylalkyl diethylenetriamine, and mixtures thereof and a multi-podal aminosilane including bis(trialkoxysilylalkyl)amine, N,N′-bis[(3-trialkoxysilyl)alkyl]ethylenediamine, tris(trialkoxysilylalkyl) amine, and mixtures thereof. In certain preferred embodiments, the colloidal silica particles may be covalently bonded with a mono-podal aminosilane including multiple amine groups such as trialkoxysilylalkyl ethylenediamine or trialkoxysilylalkyl diethylenetriamine and a bi-podal aminosilane such as bis(trialkoxysilylalkyl)amine (in addition to the second silicon containing compound described in more detail below).

Those of ordinary skill in the art will readily appreciate that silicon containing compounds are commonly hydrolyzed (or partially hydrolyzed) in an aqueous medium. Thus, by reciting an aminosilane compound, it will be understood that the modifying aminosilane may include a hydrolyzed (or partially hydrolyzed) species that generates silanols and/or self-condensed species thereof and that these species may covalently bond to colloidal silica. Moreover, it will further be appreciated, that the above described silicon containing compounds may be further described as the compounds in which the alkoxysilane group is replaced by another hydrolizable group such as a halosilane or amide silane since these species generally hydrolize in water to produce similar silanol containing aminosilanes.

The dual silane modified colloidal silica particles may have substantially any suitable modification level of the first silicon containing compound. For example, the modification level of the first silicon containing compound may be at least about 2 percent (e.g., at least about 5 percent, at least about 8 percent, or at least 10 percent). As used herein, the modification level of the first silicon containing compound is defined as the ratio of the number silicon atoms in the first silicon containing compound to the number of the available surface silanol groups on the colloidal silica. For the purposes of this disclosure, the number of the available silanol groups on the colloidal silica may be estimated to be 4.5 per nm² of surface area. The modification level of the first silicon containing compound may be determined theoretically from the amount of the compound added during synthesis and the total surface area of the silica particles. The modification level of the first silicon containing compound may be measured, for example, using nuclear magnetic resonance (NMR) as described in more detail below in Example 2. The modification level of the first silicon containing compound may also be determined using mass spectroscopy or a combination of mass spectroscopy and NMR. The theoretical modification level may be close to the measured modification level when most of the added silicon containing compound bonds with the colloidal silica particles and the amount left in solution is insignificant (e.g., less than about 10 percent of the amount added, less than about 5 percent of the amount added, less than about 2 percent of the amount added, or less than about 1 percent of the amount added). In certain embodiments, it may be desirable that the amount of the first silicon containing compound remaining in solution is less than about 0.2 mmol/liter (e.g., less than about 0.1 mm/liter).

The modification level of the first silicon containing compound may also be quantified as an amount of the compound (such as a number of moles) per unit area of the colloidal silica particles, for example, as measured via NMR or mass spectroscopy. In example embodiments, the modification level of the first silicon containing compound may be at least about 0.05 μmol per m² of BET surface area (e.g., at least about 0.1 μmol per m², at least about 0.15 μmol per m², at least about 0.2 μmol per m², or at least about 0.25 μmol per m²).

The second silicon containing compound may include substantially any suitable silicon containing compound. The second silicon containing compound is preferably not a polymer. In example embodiments, the second silicon containing compound includes a nonionic compound such that it doesn't impart a charge (e.g., positive or negative) to the colloidal silica particles. Example nonionic silicon containing compounds may include, for example, an alkyl silane, an aryl silane, a silyl ether (siloxane), an alkenyl silane, an alky alkoxy silane, an alkyl acetoxy silane, an acryloxy silane, an alkynyl silane, a haloalkyl silane, a cyano alky silane, or a mixture thereof.

In certain advantageous embodiments, the second silicon containing compound is a hydrophobic compound. As used herein the term “hydrophobic” refers to a compound that has a theoretical octanol/water distribution coefficient logarithm (Log D) that is greater than 0 after hydrolysis of the silicon containing compound at the pH of the polishing composition. In example embodiments, the second silicon containing compound may have a Log D that is greater than about 0.4 at the pH of the polishing composition (e.g., greater than 0.6, greater than about 0.8, or greater than about 1). Moreover, in some embodiments, the second silicon containing compound may have a Log D that is less than about 2 at the pH of the composition (e.g., less than about 1.8, less than about 1.6, or less than about 1.4). Accordingly, the second silicon containing compound may have a Log D that is in a range bounded by any two of the aforementioned endpoints (e.g., from about 0.4 to about 2, from about 0.6 to about 1.8, from about 0.6 to about 1.4, from about 0.8 to about 1.6, or from about 1 to about 1.4).

In certain preferred embodiments, the second silicon containing compound includes a silicon containing ester compound having the following chemical formula:

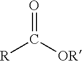

In ester compound embodiments, R may include a branched or straight chain alkane or alkene group. In preferred silicon containing ester compounds, R includes at least 2 carbon atoms and most preferably at least 3 carbon atoms. In preferred silicon containing ester compounds, R′ includes an optional intervening group (such as an intervening alkyl or substituted alkyl group) and a silicon containing group (such as a trialkoxysilane group). In most preferred embodiments, R′ includes an intervening alkyl group having at least 2 carbon atoms (e.g., a propyl group) and a trialkoxysilane group.

Example silicon containing ester compounds having the foregoing chemical formula may include an acrylate silane, such as acryloxymethyl trialkoxysilane (such as CAS No. 21134-38-3), acryloxypropyl trialkoxysilane (such as CAS No. 4369-14-6), or (3-(trialkoxysilyl)alkyl methacrylate (such as CAS No. 2530-80-0). Methacrylate silanes, such as (3-(trialkoxysilyl)alkyl methacrylate, are most preferred. Example non-acrylate silanes may include isobutyryloxy trialkoxysilane, trialkoxysilylpropyl pivalate, acetoxypropyl trialkoxysilane, and acetamindopropyl trialkoxysilane.

In other advantageous embodiments, the second silicon containing compound comprises a silicon containing amide compound having the following chemical formula:

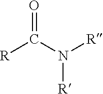

In amide compound embodiments, R may include a branched or straight chain alkane or alkene group. In preferred embodiments, R includes at least 3 carbon atoms and most preferably at least 4 carbon atoms (e.g., 6 carbon atoms). R′ includes H or a short chain alkane or alkene group having less than 4 carbon atoms (3 or less). R″ may include an optional intervening group (such as an intervening alkyl or substituted alkyl group) and a silicon containing group (such as a trialkoxysilane group). In preferred embodiments, the intervening group includes an alkyl group having at least 2 carbon atoms and most preferably at least 3 carbon atoms (e.g., a propyl group). Such silicon containing amide compounds may be particularly advantageous in polishing compositions having a pH greater than about 5 (e.g. greater than about 6 or greater than about 7). Example amide silane compounds may include trialkoxysilylpropyl cyclohexyl caboxamide), trialkoxysilylpropyl cyclohexane caboxamide, (trialkoxysilylpropyl neopentyl caboxamide), N-Benzyl-3-trialkoxysilylpropionamide, and N-Octyl-3-trialkoxysilylpropionamide.

The dual silane modified colloidal silica particles may have a modification level of the second silicon containing compound of at least 20 percent (e.g., at least 25 percent, at least 30 percent, at least 40 percent, at least 50 percent, at least 60 percent, or at least 80 percent). As used herein, the modification level of the second silicon containing compound is defined as the ratio of the number silicon atoms in the compound to the number of the available surface silanol groups on the colloidal silica. As noted above, the number of the available silanol groups on the colloidal silica may be estimated to be 4.5 per nm² of surface area. The modification level of the second silicon containing compound may be determined theoretically from the amount of the compound added during synthesis and the total surface area of the silica particles. The modification level of the second silicon containing compound may be measured, for example, using NMR and/or mass spectroscopy. The theoretical modification level may be close to the measured modification level when most of the added silicon containing compound bonds with the colloidal silica particles and the amount left in solution is insignificant (e.g., less than about 10 percent of the amount added, less than about 5 percent of the amount added, less than about 2 percent of the amount added, or less than about 1 percent of the amount added).

The modification level of the second silicon containing compound may also be quantified as an amount of the compound (such as a number of moles) per unit area of the colloidal silica particles, for example, as measured via NMR or mass spectroscopy. In example embodiments, the modification level of the second silicon containing compound may be at least about 0.5 μmol per m² of BET surface area (e.g., at least about 1 μmol per m², at least about 1.5 μmol per m², at least about 2 μmol per m², or at least about 2.5 μmol per m², at least about 3 μmol per m², at least about 3.5 μmol per m², or at least about 4 μmol per m²).

In example embodiments, the polishing composition including the dual silane modified colloidal silica particles has less than about 50 ppm (e.g., less than about 40 ppm, less than about 30 ppm, less than about 20 ppm, or less than about 10 ppm) of the first silicon containing compound (or each of the first and second silicon containing compounds) free in the liquid carrier per 1 weight percent of the dual silane modified colloidal silica particles. By free it is meant that modifying aminosilane compounds are not bound to the particle (e.g., dissolved in the liquid carrier or agglomerated and suspended in the liquid carrier). Thus, for example, a polishing composition including 0.3 weight percent of the dual silane modified colloidal silica particles preferably has less than about 15 ppm (e.g., less than about 12 ppm, less than about 9 ppm, less than about 6 ppm, or less than about 3 ppm) of each of the first and second silicon containing compounds free in the liquid carrier. Likewise, a polishing composition including 3 weight percent of the dual silane modified colloidal silica particles (e.g., a concentrated composition) preferably has less than about 150 ppm (e.g., less than about 120 ppm, less than about 90 ppm, less than about 60 ppm, or less than about 30 ppm) of each of the first and second silicon containing compounds free in the liquid carrier.

The amount of the first (or first and second) silicon containing compound(s) free in the liquid carrier may also be expressed as a molar or millimolar quantity such that that the amount of free silicon containing compound is less than about 0.2 mmol/liter (e.g., less than about 0.15 mmol/liter, less than about 0.1 mmol/liter, or less than about 0.05 mm/liter) per 1 weight percent of the dual silane modified colloidal silica particles. In certain embodiments in which the first silicon containing compound is an aminosilane, it may be particularly advantageous that the amount free in the composition is less than the aforementioned amounts.

It will be appreciated that the dual silane modified colloidal silica particles may be thought of as being co-modified in the sense that both the first silicon containing compound and the second silicon containing compound are covalently bonded with the colloidal silica particles. Such co-modification may occur in any order during the synthesis of the modified colloidal silica particles. For example, the colloidal silica particles may be modified with the first and second silicon containing compounds at the same time (e.g., in a single reaction vessel). In other embodiments the colloidal silica particles may be first modified with the first silicon containing compound and then later modified with the second silicon containing compound. In still other embodiments the colloidal silica particles may be first modified with the second silicon containing compound and then later modified with the first silicon containing compound. Moreover, in some example embodiments, the dual silane modified colloidal silica particles may be further modified (modified another time) with the first or second (or even a third) silicon containing compound such that the modification (synthesis) process may include numerous modification steps. The disclosed embodiments are expressly not limited in these regards.

The disclosed dual silane modified colloidal silica particles may include substantially any suitable molar ratio of the second silica containing compound (e.g., the nonionic compound) to the first silica containing compound (e.g., the aminosilane compound) to achieve a charge and a desired chemical mechanical polishing performance. In preferred embodiments, the molar ratio of the second silica containing compound to the first silica containing compound is greater than about 1:1 (e.g., greater than about 2:1, greater than about 3:1, greater than about 4:1, greater than about 4.5 to 1, greater than about 5:1, greater than about 6:1, greater than about 7:1, or greater than about 8:1). The molar ratio may be determined, for example, using NMR and/or mass spectroscopy measurements to measure the amount of each of the first and second silicon containing compounds on the dual silane modified colloidal silica particles. For example, the dual silane modified colloidal silica particles may be extracted from the composition via centrifugation, digested in concentrated KOH, and evaluated via 1H NMR analysis as described in Example 2. When organic compounds are present in solution, they should be removed prior to digesting the particles (e.g., via centrifuge-wash-rinse cycles, ultra filtration, dialysis, etc.).

The combined modification level of the first and second silicon containing compounds may be estimated via a Sear's titration (e.g., as described below in Example 2). The procedure for making a Sear's titration follows the method described in G.W. Sears, Jr., Analytical Chemistry, 28(12), 1981 (1956). More specifically, in the Sears method, using a 1% by mass silica dispersion, a titration is performed with a 0.1M sodium hydroxide solution. The Sear's number may be determined using the following equation:

$$Sear ' s \# = \frac{60.2 \cdot V}{A \cdot SSA}$$

where Sear's #represents the amount of titratable species (such as the silanol group density in units of OH/nm²), V represents the volume (in ml) of 0.1M NaOH raise the pH from 4 to 9 (the Sear's titration), A represents the mass of the silica (in grams), and SSA represents the BET surface area of the silica (in m²/g). If significant amounts of other titratable species are present in the pH range from about 4 to about 9 they should be removed (e.g., via ion exchange, dialysis, ultrafiltration, etc.).

In advantageous embodiments, the Sear's number (also referred to as a silanol number) of the dual silane modified colloidal silica particles may be less than about 2 OH/nm² (e.g., less than about 1.8 OH/nm², less than about 1.6 OH/nm², less than about 1.5 OH/nm², less than about 1.4 OH/nm², less than about 1.3 OH/nm², less than about 1.2 OH/nm², less than about 1.1 OH/nm², less than about 1.0 OH/nm², less than about 0.9 OH/nm², or less than about 0.8 OH/nm²).

The combined modification level of the first and second silicon containing compounds may also be estimated via measuring the total (or percent) carbon in the dual silane modified colloidal silica particles. It will be appreciated that the first and second silicon containing compounds contain carbon (while the colloidal silica particles usually contain little or no carbon) such that a measure of the total carbon may be taken to be a measure of the combined modification level. As disclosed herein, the total carbon is estimated via combusting the dual silane modified colloidal silica particles in an oxygen rich environment and determining the amount of carbon in the particles from the amount of carbon dioxide generated during combustion. For example, samples of the dual silane modified colloidal silica particles may be obtained via centrifugation, washing, and oven drying a corresponding dispersion. A known (measured) mass may then be combusted and the quantity of CO₂ determined via gas chromatography to determine the total carbon in each sample. When carbon containing compounds are present in solution, these carbon containing compounds should be removed from the solution prior to drying and combusting the particles (e.g., via centrifuge-wash-rinse cycles, ultra filtration, dialysis, etc.).

It will be appreciated that an increasing combined modification level results in an increasing total carbon from the covalently bonded organics. In example embodiments, the dual silane modified colloidal silica particles may have a percent carbon of at least 0.5 percent (e.g., at least about 0.6 percent, at least about 0.7 percent, at least about 0.8 percent, at least about 0.9 percent, or at least about 1 percent). The amount of carbon may also be quantified based on the BET surface area of the colloidal silica particle, for example, as a number of carbon atoms per nm². In example embodiments, the dual silane modified colloidal silica particles may have at least 5 carbon atoms per nm² of BET surface area (e.g., at least 8 carbon atoms per nm², at least 10 carbon atoms per nm², at least 12 carbon atoms per nm², at least 14 carbon atoms per nm², at least 16 carbon atoms per nm², at least 18 carbon atoms per nm², or at least 20 carbon atoms per nm²).

The modification level of the first positively charged silicon containing compound is preferably sufficiently high such that the zeta potential of the dual silane modified colloidal silica particles in the composition is at least 10 mV (e.g., at least 15 mV, at least 20 mV, at least 25 mV, or at least 30 mV) in a composition having a pH of less than about 4 (e.g. less than about 3.5, or less than about 3). In advantageous embodiments, the zeta potential of the dual silane modified colloidal silica particles in the composition is at least 20 mV and is preferably at least 30 mV. For the purposes of this disclosure the zeta potential is as measured in the point of use polishing composition (with the exception that the composition does not include hydrogen peroxide) using the electroacoustic method (e.g., using a Zetaprobe Analyzer®) (with no Smoluchowski correction applied).

Moreover, the isoelectric point (IEP) of the dual silane modified colloidal silica particles is preferably at least about 5 (e.g., at least about 6, at least about 7, at least about 7.5, or at least about 8). For the purposes of this disclosure the IEP is measured on the as-modified dual silane modified colloidal particles before the addition of other polishing composition compounds (e.g., the iron-containing accelerator). The IEP is determined by titrating a sample using the electroacoustic method (e.g., via a Colloidal Dynamics Zetaprobe). The dispersion of the dual silane modified colloidal particles is diluted in deionized water to a solids (particle) concentration in a range from 2 to 5 weight percent. The diluted sample is titrated with 0.1N potassium hydroxide for a base titration (sample pH to 10.5). The zeta potential is measured using a Zetaprobe Analyzer® at least every 0.5 pH units during the titration. The IEP is identified by determining the pH value at which the zeta potential is 0 mV. The precise IEP value may be computed via interpolation between the pH values at which the zeta potential transitions from positive to negative.

While the disclosed embodiments are expressly not limited in this regard, one aspect of the invention was the realization that highly modified and highly charged colloidal silica particles may be particularly advantageous in a number of CMP operations. For example, it was realized that such colloidal silica particles may be advantageously utilized in CMP compositions that have a pH that is mildly acidic or neutral (e.g., at pH>5) and may therefore be effective for cobalt, copper, and ruthenium CMP applications. It was further realized that colloidal silica particles having a high IEP and a low Sear's number may be equally advantageous. In example embodiments, the disclosed CMP compositions include colloidal silica particles having an IEP greater than about 8 (e.g., greater than about 8.2, greater than about 8.4, or greater than about 8.6) and a Sear's number less than about 1 (e.g., less than about 0.9 or less than about 0.8).

In example embodiments, the dual silane modified colloidal silica particles in the polishing composition are substantially all dual silane modified colloidal silica particles. In other words, the polishing composition does not include a significant amount of colloidal silica or agglomerated silane particles other than the dual silane modified colloidal silica particles. By significant amount it is meant that less than about 1 percent (number fraction) of the particles (e.g. less than about 0.5%) are colloidal silica particles or agglomerated silane particles (non-composite particles).

In preferred embodiments, the first and second silicon containing compounds may be covalently bonded with the surface of the colloidal silica particles. The term covalent (as in covalently bonded) is used in its ordinary sense herein. Such covalent bonding between the colloidal silica particles and the silicon containing compounds may be evident (or identified), for example, from the methodology used to synthesize the dual silane modified colloidal silica particles. Covalent bonding may also be evident (or identified), for example, when the silicon containing compounds remain bonded to the colloidal silica particles after flushing, dilution, filtration, and the like.

In other example embodiments, the polishing composition does not include a significant amount of fine (very small) particles. By fine it is meant particles having a particle diameter in a range from about 5 nm to about 25 nm. By significant amount it is meant that less than about 1 percent (number fraction) (e.g., less than about 0.5 percent or less than about 0.3 percent) of the particles are fine. The number of fine particles may be measured, for example, using differential mobility analysis (DMA).

A liquid carrier is generally used to facilitate the application of the treated composite particles and any optional chemical additives to the surface of the substrate to be polished. The liquid carrier may include any suitable carrier (e.g., a solvent) including lower alcohols (e.g., methanol, ethanol, etc.), ethers (e.g., dioxane, tetrahydrofuran, etc.), water, and mixtures thereof. Preferably, the liquid carrier comprises, consists essentially of, or consists of water, more preferably deionized water.

The polishing composition may be acidic or mildly acidic having a pH of less than about 7 (e.g., less than about 6). The polishing composition may have a pH of about 1 or more (e.g., about 1.5 or more or about 2 or more). Moreover, the polishing composition may have a pH of about 7 or less (e.g., about 6 or less, about 5 or less, about 4.5 or less, about 4 or less, about 3.5 or less, or about 3 or less). According, the polishing composition may have a pH in a range bounded by any two of the aforementioned endpoints, for example, in a range from about 1 to about 7 (e.g., from about 1.5 to about 5, from about 1.5 to about 4, from about 2 to about 3.5, or from about 2 to about 3). In advantageous embodiments formulated for tungsten or molybdenum CMP applications, the composition may advantageously have a pH in a range from about 2 about 4 (e.g., from about 2 to about 3).

The pH of the polishing composition may be achieved and/or maintained by any suitable means. The polishing composition may include substantially any suitable pH adjusting agents or buffering systems. For example, suitable pH adjusting agents may include nitric acid, sulfuric acid, phosphoric acid, phthalic acid, citric acid, adipic acid, oxalic acid, malonic acid, maleic acid, ammonium hydroxide, and the like while suitable buffering agents may include phosphates, sulfates, acetates, malonates, oxalates, borates, ammonium salts, and the like.

Disclosed polishing compositions may include substantially any suitable chemical mechanical polishing additives, for example, including a chelating agent, a topography control agent, an etch inhibitor, an oxidizer, a polishing rate accelerator, a dispersant, and/or a biocide. Advantageous embodiments may be formulated for polishing tungsten, molybdenum, or other metal layers and may include, for example, an oxidizing agent, a polishing rate accelerating agent such synthesis as iron-containing accelerator, a topography control agent, and/or an etch inhibitor, however, the disclosed embodiments are not limited to tungsten and/or molybdenum polishing compositions or even to other metal polishing compositions. The disclosed embodiments may be utilized to polish substantially any dielectric or metal found in semiconductor devices.

In example embodiments, the disclosed polishing composition may be configured for polishing at least one metal layer. In such embodiments, the polishing composition may further include a metal polishing accelerator such as an oxidizer, a chelating or complexing agent, a catalyst, or any other suitable compound that increases the polishing rate of the metal layer. For example, an iron-containing compound may be used to increase the polishing rate of tungsten and/or molybdenum layers. The iron-containing compound may include a soluble iron-containing catalyst such as is disclosed in U.S. Pat. Nos. 5,958,288 and 5,980,775. Such an iron-containing catalyst may be soluble in the liquid carrier and may include, for example, ferric (iron III) or ferrous (iron II) compounds such as iron nitrate, iron sulfate, iron halides, including fluorides, chlorides, bromides, and iodides, as well as perchlorates, perbromates and periodates, and organic iron compounds such as iron acetates, carboxylic acids, acetylacetonates, citrates, gluconates, malonates, oxalates, phthalates, and succinates, and mixtures thereof.

An iron-containing accelerator may also include an iron-containing activator (e.g., a free radical producing compound) or an iron-containing catalyst associated with (e.g., coated or bonded to) the surface of the colloidal silica particle such as is disclosed in U.S. Pat. Nos. 7,029,508 and 7,077,880. For example, the iron-containing accelerator may be bonded with the silanol groups on the surface of the colloidal surface particles.

The amount of iron-containing accelerator in the polishing composition may be varied depending upon the oxidizing agent used and the chemical form of the accelerator. When the oxidizing agent is hydrogen peroxide (or one of its analogs) and a soluble iron-containing catalyst is used (such as ferric nitrate or hydrates of ferric nitrate), the catalyst may be present in the composition at point of use in an amount sufficient to provide a range from about 0.5 to about 3000 ppm Fe based on the total weight of the composition. For example, polishing compositions configured for bulk tungsten or molybdenum removal may include about 1 ppm Fe or more at point of use (e.g., about 5 ppm or more, about 10 ppm or more, or about 15 ppm or more). The polishing composition may include about 500 ppm Fe or less at point of use (e.g., about 200 ppm or less, about 100 ppm or less, or about 50 ppm or less). Accordingly, the point of use polishing composition may include Fe in a range bounded by any one of the above endpoints (e.g., from about 1 ppm to about 500 ppm, from about 5 ppm to about 200 ppm, from about 10 ppm to about 100 ppm, or from about 15 ppm to about 50 ppm). For tungsten or molybdenum buff applications that do not require high metal removal rates, the catalyst may be present in lower amounts, for example, from about 0.1 ppm to about 50 ppm Fe (e.g., from about 0.2 ppm to about 20 ppm or from about 0.2 to about 10 ppm) at point of use.

Embodiments of the polishing composition including an iron-containing accelerator may further include a stabilizer. Without such a stabilizer, the iron-containing accelerator and the oxidizing agent, if present, may react in a manner that degrades the oxidizing agent rapidly over time. The addition of a stabilizer tends to reduce the effectiveness of the iron-containing accelerator such that the choice of the type and amount of stabilizer added to the polishing composition may have a significant impact on CMP performance. The addition of a stabilizer may lead to the formation of a stabilizer/accelerator complex that inhibits the accelerator from reacting with the oxidizing agent, if present, while at the same time allowing the accelerator to remain sufficiently active so as to promote rapid tungsten or molybdenum polishing rates.

Useful stabilizers include phosphoric acid, organic acids such as polycarboxylic acids (e.g., dicarboxylic acids), phosphonate compounds, nitriles, and other ligands which bind to the metal and reduce its reactivity toward hydrogen peroxide decomposition and mixture thereof. The acid stabilizers may be used in their conjugate form, e.g., the carboxylate can be used instead of the carboxylic acid. The term “acid” as it is used herein to describe useful stabilizers also means the conjugate base of the acid stabilizer. Stabilizers can be used alone or in combination and significantly reduce the rate at which oxidizing agents such as hydrogen peroxide decompose.

Preferred stabilizers include phosphoric acid, acetic acid, phthalic acid, citric acid, adipic acid, oxalic acid, malonic acid, aspartic acid, succinic acid, glutaric acid, pimelic acid, suberic acid, azelaic acid, sebacic acid, maleic acid, glutaconic acid, muconic acid, ethylenediaminetetraacetic acid (EDTA), propylenediaminetetraacetic acid (PDTA), and mixtures thereof. The preferred stabilizers may be added to the compositions of this invention in an amount ranging from about 1 equivalent per iron-containing accelerator to about 3.0 weight percent or more (e.g., from about 1 equivalent to about 5 equivalents, or from about 3 equivalents to about 10 equivalents). As used herein, the term “equivalent per iron-containing accelerator” means one molecule of stabilizer per iron ion in the composition. For example, two equivalents per iron-containing accelerator means two molecules of stabilizer for each catalyst ion.

The polishing composition may optionally further include an oxidizing agent. The oxidizing agent may be added to the polishing composition during the slurry manufacturing process or just prior to the CMP operation (e.g., in a tank located at the semiconductor fabrication facility). Preferred oxidizing agents include inorganic or organic per-compounds. A per-compound as defined herein is a compound containing at least one peroxy group (—O—O—) or a compound containing an element in its highest oxidation state. Examples of compounds containing at least one peroxy group include but are not limited to hydrogen peroxide and its adducts such as urea hydrogen peroxide and percarbonates, organic peroxides such as benzoyl peroxide, peracetic acid, and di-t-butyl peroxide, monopersulfates (SO₅⁻), dipersulfates (S₂O₈^{═}), and sodium peroxide. Examples of compounds containing an element in its highest oxidation state include but are not limited to periodic acid, periodate salts, perbromic acid, perbromate salts, perchloric acid, perchlorate salts, perboric acid, and perborate salts and permanganates. The most preferred oxidizing agent is hydrogen peroxide.

The oxidizing agent may be present in the polishing composition in substantially any suitable amount, for example, from about 0.0 wt. % to about 20 wt. % at point of use. In example embodiments configured for bulk tungsten or molybdenum removal that include a hydrogen peroxide oxidizer and a soluble iron-containing catalyst, the oxidizer may be present in the polishing composition in an amount ranging from about 0.1 wt. % to about 10 wt. % at point of use (e.g., from about 0.5 wt. % to about 5 wt. % or from about 1 wt. % to about 4 wt. %). In example embodiments configured for buff tungsten or molybdenum applications, the amount of hydrogen peroxide in the composition is generally less, for example, from about 0 wt. % to about 1 wt. %.

The polishing composition may further include a metal etch inhibitor and/or a topography control agent. Suitable etch inhibitor compounds may inhibit the conversion of solid metal (such as solid tungsten or molybdenum) into soluble compounds while at the same time allowing for effective removal of the metal via the CMP operation. The polishing composition may include substantially any suitable inhibitor, for example, inhibitor compounds disclosed in commonly assigned U.S. Pat. Nos. 9,238,754; 9,303,188; and 9,303,189.

Example classes of compounds that that may be useful etch inhibitors include compounds having nitrogen containing functional groups such as nitrogen containing heteroycles, alkyl ammonium ions, amino alkyls, and amino acids. Useful amino alkyl corrosion inhibitors include, for example, hexylamine, tetraalkyl-p-phenylene diamine, octylamine, diethylene triamine, dialkyl benzylamine, aminoalkylsilanol, aminoalkylsiloxane, dodecylamine, mixtures thereof, and synthetic and naturally occurring amino acids including, for example, lysine, tyrosine, glutamine, glutamic acid, arginine, histidine, aspartic acid, cystine, and glycine (aminoacetic acid).

Suitable compounds may alternatively and/or additionally include an amine compound in solution in the liquid carrier. The amine compound (or compounds) may include a primary amine, a secondary amine, a tertiary amine, or a quaternary amine. The amine compound may further include a monoamine, a diamine, a triamine, a tetramine, or an amine based polymer having a large number of repeating amine groups (e.g., 4 or more amine groups).

Suitable compounds may alternatively and/or additionally include a cationic surfactant. The use of a cationic surfactant may advantageously reduce the metal etch rate and improve planarity (e.g., reducing dishing and/or erosion). In certain embodiments, the polishing compound may include a nitrogen containing cationic surfactant, such as a quaternary amine compound or a polyquaternary amine compound. By polyquaternary amine it is meant that the compound includes from 2 to 4 quaternary ammonium groups such that the polyquaternary amine is a diquaternary amine compound, a triquaternary amine compound, or a tetraquaternary amine compound. Diquaternary amine compounds may include, for example, N,N′-alkylenebis(dialkylteradecylammonium bromide), N,N,N′,N′,N′-pentaalkyl-N-tallow-1,3-propane-diammonium dichloride, N,N′-hexamethylenebis(trialkylammonium hydroxide), decamethonium bromide, didodecyl-tetraalkyl-1,4-butanediaminium diiodide, 1,5-dialkyl-1,5-diazoniabicyclo(3.2.2) nonane dibromide, dialkylcocoamine bis(chloroalkyl) ether diquaternary ammonium salt, and the like. Triquaternary amine compounds may include, for example, N (1),N (6)-didoecyl-N(1),N (1),N (6),N (6)-tetraalkyl-1,6-hexanediaminium diiodide. Tetraquaternary amine compounds may include, for example, methanetetrayltetrakis(tetraalkylammonium bromide). The polyquaternary amine compound may further include a long chain alkyl group (e.g., having 10 or more carbon atoms), For example, a polyquaternary amine compound having a long chain alkyl group may include N,N′-methylenebis(dialkyltetradecylammonium bromide), N,N,N′,N′,N′-pentaalkyl-N-tallow-1,3-propane-diammonium dichloride, didodecyl-tetraalkyl-1,4-butanediaminium di iodide, and N (1),N (6)-didodecyl-N(1),N (1),N (6),N (6)-tetraalkyl-1,6-hexanediaminium diiodide.

Suitable compounds may alternatively and/or additionally include a cationic polymer. Example cationic polymers include but are not limited to poly(vinylimidazolium), poly(methacryloyloxyalkyltrimethylammonium) chloride (polyMADQUAT), poly(diallyldimethylammonium) chloride (polyDADMAC) (e.g., Polyquaternium-6), poly(dialkylamine-co-epichlorohydrin), poly[bis(2-chloroethyl) ether-alt-1,3-bis[3-(dialkylamino)alkyl]urea] (e.g., Polyquaternium-2), copolymers of hydroxyalkyl cellulose and diallyldialkylammonium (e.g., Polyquaternium-4), copolymers of acrylamide and diallyldialkylammonium (e.g., Polyquaternium-7), quaternized hydroxyalkylcellulose ethoxylate (e.g., Polyquaternium-10), copolymers of vinylpyrrolidone and quaternized dialkylaminoalkyl methacrylate (e.g., Polyquaternium-11), copolymers of vinylpyrrolidone and quaternized vinylimidazole (e.g., Polyquaternium-16), Polyquaternium-24, a terpolymer of vinylcaprolactam, vinylpyrrolidone, and quaternized vinylimidazole (e.g., Polyquaternium-46), 3-Alkyl-1-vinylimidazolium alkyl sulfate-N-vinylpyrrolidone copolymer (e.g., Polyquaternium-44), and copolymers of vinylpyrrolidone and diallyldialkylammonium. Additionally, suitable cationic polymers include cationic polymers for personal care such as Luviquat® Supreme, Luviquat® Hold, Luviquat® UltraCare, Luviquat® FC 370, Luviquat® FC 550, Luviquat® FC 552, Luviquat® Excellence, GOHSEFIMER K210™, GOHSENX K-434, and combinations thereof.

Cationic polymers may also include an amino acid monomer (such compounds may also be referred to as polyamino acid compounds). Suitable polyamino acid compounds may include substantially any suitable amino acid monomer groups, for example, including polyarginine, polyhistidine, polyalanine, polyglycine, polytyrosine, polyproline, and polylysine. In example embodiments, polylysine may be a preferred polyamino acid. It will be understood that polylysine may include &-polylysine and/or α-polylysine composed of D-lysine and/or L-lysine. The polylysine may thus include α-poly-L-lysine, α-poly-D-lysine, ε-poly-L-lysine, ε-poly-D-lysine, and mixtures thereof. The most preferred polylysine is &-poly-L-lysine. It will further be understood that the polyamino acid compound (or compounds) may be used in any accessible form, e.g., the conjugate acid or base and salt forms of the polyamino acid may be used instead of (or in addition to) the polyamino acid.

In certain advantageous embodiments, the polishing composition may include first and second distinct inhibitor compounds. For example, the first inhibitor compound in the composition may include a cationic polymer such as a polyamino acid (with polylysine being preferred) and the second inhibitor compound in the composition may include an amino acid (with glycine, arginine, and a histidine being preferred).

The disclosed polishing compositions may include substantially any suitable concentration of the inhibitor compound and/or topography control agent. In general, the concentration is desirably high enough to provide adequate etch inhibition and topography control, but low enough so that the compound is soluble and so as not to reduce tungsten polishing rates below acceptable levels. By soluble it is meant that the compound is fully dissolved in the liquid carrier or that it forms micelles in the liquid carrier or is carried in micelles. It may be necessary to vary the concentration of the inhibitor compound depending upon numerous various factors, for example, including the solubility thereof, the number of amine groups therein, the length of an alkyl group, the relationship between etch rate inhibition and polishing rate inhibition, the oxidizing agent used, the concentration of the oxidizing agent, and so on. In example embodiments, the concentration of an amine compound in the polishing composition may be in a range from about 1 ppm by weight to about 200 ppm by weight at point of use (e.g., from about 5 ppm to about 100 ppm or from about 10 ppm to about 50 ppm). In example embodiments that include a cationic polymer, the concentration of the cationic polymer in the polishing composition may be in a range from about 0.1 ppm by weight to about 50 ppm by weight at point of use (e.g., from about 0.5 ppm to about 20 ppm or from about 1 ppm to about 10 ppm). In example embodiments that include a cationic surfactant, the concentration of the cationic surfactant in the polishing composition may be in a range from about 0.1 ppm by weight to about 100 ppm by weight at point of use (e.g., from about 1 ppm to about 50 ppm, from about 5 ppm to about 40 ppm, or from about 10 ppm to about 30 ppm).

The polishing composition may optionally further include a biocide. The biocide may include any suitable biocide, for example an isothiazolinone biocide. The amount of biocide in the polishing composition typically is in a range from about 1 ppm to about 50 ppm by weight at point of use or in a concentrate, and preferably from about 1 ppm to about 20 ppm.

In the disclosed embodiments, the dual silane modified colloidal silica particles may be prepared, for example, by bonding both the first and the second silicon containing compounds to the surface of colloidal silica particles in a dispersion. As noted above, the first and second compounds may be bonded to the colloidal silica simultaneously or in either order. For example only, an admixture of colloidal silica particles, the first silicon containing compound, and the second silicon containing compound may be prepared at an acidic pH (e.g., from about 1 to about 4) to obtain a colloidal silica dual-silane mixture. The mixture may be heated, for example, to a temperature of at least 50 degrees C to promote covalent bonding of the first and the second silicon containing compounds to the colloidal silica. In preferred embodiments, the synthesis process is a wet process meaning that the colloidal silica particles are never dried. Moreover, in preferred embodiments, at least 90 percent (e.g., at least 95 percent, at least 98 percent, or at least 99 percent) of the added silane compounds are bonded to the surface of the silica particles such that less than 10 percent (e.g., less than 5 percent, less than 2 percent, or less than 1 percent) of the added silane compounds remain in solution after reacting the silane compounds with the colloidal silica particles.

The disclosed polishing composition may be prepared by admixing one or more CMP polishing components with the dispersion of the dual silane modified colloidal silica particles. Any suitable techniques may be used; many of which are known to those skilled in the art. The polishing composition may be prepared in a batch or continuous process. Generally, the polishing composition may be prepared by combining the components thereof in any order. The term “component” as used herein includes the individual ingredients (e.g., the colloidal silica, the iron-containing accelerator, the amine compound, etc.).

For example, the polishing composition components (such as an iron-containing accelerator, a stabilizer, an inhibitor, and/or a biocide) may mixed together with an appropriate amount of water. A dispersion of the dual silane modified colloidal silica particles may then be added to and blended with the mixture. The dispersion may be passed through a cationic ion exchange column prior to adding it to the above mixture. Substantially any suitable blending techniques may be used for achieving adequate mixing. Such blending/mixing techniques are well known to those of ordinary skill in the art. An optional oxidizing agent may be added at any time during the preparation of the polishing composition. For example, the polishing composition may be prepared prior to use, with one or more components, such as the oxidizing agent, being added just prior to the CMP operation (e.g., within about 1 minute, or within about 10 minutes, or within about 1 hour, or within about 1 day, or within about 1 week of the CMP operation). The polishing composition also may also be prepared by mixing the components at the surface of the substrate (e.g., on the polishing pad) during the CMP operation.

The polishing composition may advantageously be supplied as a one-package system comprising treated composite particles having the above described physical properties and other optional components. An oxidizing agent may be desirably supplied separately from the other components of the polishing composition and may be combined, e.g., by the end-user, with the other components of the polishing composition shortly before use (e.g., 1 week or less prior to use, 1 day or less prior to use, 1 hour or less prior to use, 10 minutes or less prior to use, or 1 minute or less prior to use). Various other two-container, or three- or more-container, combinations of the components of the polishing composition are within the knowledge of one of ordinary skill in the art.

The polishing composition of the invention may also be provided as a concentrate which is intended to be diluted with an appropriate amount of water prior to use. In such concentrated embodiments, the polishing composition concentrate may include the treated composite particles, water, and other optional components such as an iron-containing accelerator, a stabilizer, an inhibitor, and a biocide, with or without the oxidizing agent, in amounts such that, upon dilution of the concentrate with an appropriate amount of water, and an optional oxidizing agent if not already present in an appropriate amount, each component of the polishing composition will be present in the polishing composition in an amount within the appropriate ranges recited above for each component. For example, the treated composite particles and other optional components may each be present in the polishing composition in an amount that is about 2 times (e.g., about 3 times, about 4 times, about 5 times, or even about 10 times) greater than the point of use concentrations recited above for each component so that, when the concentrate is diluted with an equal volume of (e.g., 2 equal volumes of water, 3 equal volumes of water, 4 equal volumes of water, or even 9 equal volumes of water respectively), along with the oxidizing agent in a suitable amount, each component will be present in the polishing composition in an amount within the ranges set forth above for each component. Furthermore, as will be understood by those of ordinary skill in the art, the concentrate may contain an appropriate fraction of the water present in the final polishing composition in order to ensure that other components are at least partially or fully dissolved in the concentrate.

In certain preferred embodiments, the polishing composition may be provided to an end user (e.g., marketed and sold) as about a 6 times concentrate (e.g., in a range from about 5 times to about 8 times) such that the colloidal silica particles and other components may each be present in the polishing composition in an amount that is about 6 times greater (e.g., in a range from about 5 times greater to about 8 times greater) than the point of use concentrations recited above for each component. In such preferred embodiments, the end user may dilute the concentrate composition with deionized water (optionally including a desired amount of hydrogen peroxide) to obtain the point of use polishing composition.

The disclosed polishing compositions may be used to polish substantially any substrate, for example, including a metal layer such as a tungsten or molybdenum layer and a dielectric layer such as a silicon oxide layer. Certain advantageous embodiments may be particularly useful in the polishing of a substrate including at least one metal including tungsten or molybdenum and at least one dielectric material such as silicon oxide. In such applications, the metal layer may be deposited over one or more barrier layers, for example, including titanium and/or titanium nitride (TiN). The dielectric layer may be a metal oxide such as a silicon oxide layer derived from tetraethylorthosilicate (TEOS), porous metal oxide, porous or non-porous carbon doped silicon oxide, fluorine-doped silicon oxide, glass, organic polymer, fluorinated organic polymer, or any other suitable high or low-k insulating layer.

The disclosed compositions may also be used to polish carbon layers such as spin on carbon and hard carbon layers. Carbon films may be prepared using a variety of methods (such as chemical vapor deposition, spin-on, etc.) and can range in composition from amorphous carbon to more graphitic carbon with distinct D & G bands when measured with Raman spectroscopy. Carbon films are generally hydrophobic in nature and include a blend of sp2 and sp3 carbon bonds.

The polishing method of the invention is particularly suited for use in conjunction with a chemical mechanical polishing (CMP) apparatus. Typically, the apparatus includes a platen, which, when in use, is in motion and has a velocity that results from orbital, linear, or circular motion, a polishing pad in contact with the platen and moving with the platen when in motion, and a carrier that holds a substrate to be polished by contacting and moving relative to the surface of the polishing pad. The polishing of the substrate takes place by the substrate being placed in contact with the polishing pad and the polishing composition of the invention and then the polishing pad moving relative to the substrate, so as to abrade at least a portion of the substrate (such as tungsten, titanium, titanium nitride, and/or a dielectric material as described herein) to polish the substrate.

The disclosed embodiments may be particularly well suited for bulk tungsten or molybdenum removal (which are sometimes referred to as first step CMP operations). As known to those of ordinary skill in the art, metal CMP operations commonly include a bulk process that is intended to remove at least a portion the tungsten or molybdenum overlayer (e.g., most or all of the overlayer) and a buff process intended to remove at least a portion of one of the barrier layer(s) (e.g., titanium or titanium nitride) and eliminate defects imparted by the bulk process. In certain advantageous embodiments, the disclosed polishing composition may provide for high planarization efficiency to be achieved for a substrate having a tungsten or molybdenum layer and a dielectric layer. For example, low array erosion, dishing, and/or patterned oxide loss may be achieved using the disclosed compositions.

A substrate may be planarized or polished with the chemical mechanical polishing composition with any suitable polishing pad (e.g., polishing surface). Suitable polishing pads include, for example, woven and non-woven polishing pads. Moreover, suitable polishing pads can comprise any suitable polymer of varying density, hardness, thickness, compressibility, ability to rebound upon compression, and compression modulus. Suitable polymers include, for example, polyvinylchloride, polyvinylfluoride, nylon, fluorocarbon, polycarbonate, polyester, polyacrylate, polyether, polyethylene, polyamide, polyurethane, polystyrene, polypropylene, co-formed products thereof, and mixtures thereof.

The following examples further illustrate the invention but, of course, should not be construed as in any way limiting its scope.

### Example 1

Three cationic dual silane modified colloidal silica dispersions were prepared (Compositions 1A, 1B, and 1C). The dual silane modified colloidal silica had a theoretical modification level of the first silicon containing compound of 22 percent and theoretical modification levels of the second silicon containing compound of 25 percent, 50 percent, and 100 percent. The preparation procedure for these dispersions was as follows. In a 2-L jacketed glass reactor equipped with mechanical stirring and a pH probe, 909 g of deionized (DI) water was charged, and the pH was adjusted to 2.2 by the slow addition of 0.9 g of 69.5% nitric acid (HNO₃) under continuous stirring. Once the desired pH was reached, 0.95 g of bis(trimethoxysilylpropyl)amine (equivalent to 460 ppm or 0.37 μmol per m² of the subsequently added colloidal silica particles) was added dropwise while maintaining the pH below 2.6 to prevent premature hydrolysis or polymerization. Afterwards, 870 g of a colloidal silica dispersion (including 23 wt. % colloidal silica with an average particle size of about 120 nm) was slowly introduced into the reactor, ensuring that the pH remained below 3.5 to maintain dispersion stability. Subsequently, an appropriate amount of a prehydrolyzed 3% solution of 3-trimethoxysilylpropyl methacrylate (MPS) was added to the particle dispersion (the amount of MPS added was 112 g for example 1A, 224 g for example 1B, and 448 g for example 1C). The reaction mixture was then heated to 75 °C and maintained at that temperature for 14 hours to promote silane condensation and covalent bonding of the first and second silicon containing compounds with the surface of the colloidal silica. After this period, 110 g of a prehydrolyzed 1% bis(trimethoxysilylpropyl)amine solution (551 ppm or 0.45 μmol per m² of the colloidal silica particles) was added, and the reaction was continued at 75 °C for an additional 10 hours. Upon completion, the mixture was cooled to room temperature and purified by passing it through an ion exchange column packed with a strong cationic resin to remove any unreacted or weakly bound aminosilane, yielding the final modified particle dispersion.

Table 1 lists the modification levels of the first and second silicon containing compounds (the aminosilane and the MPS in this example) and the corresponding amounts of MPS added to the reactor in units of ppm by weight and μM/m² of the colloidal silica.

TABLE 1

| | Aminosilane (%) | | MPS | MPS | MPS |
|---|---|---|---|---|---|
| Composition | 1^{st} Dose | 2^{nd} Dose | (%) | (ppm) | (μM/m²) |
| 1A | 10 | 12 | 25 | 1671 | 1.87 |
| 1B | 10 | 12 | 50 | 3342 | 3.74 |
| 1C | 10 | 12 | 100 | 6683 | 7.48 |

### Example 2

Various analytical measurements were made on the dispersions prepared in Example 1. These included pH, conductivity, particle size, zeta potential, IEP, Sear's number, total carbon, and NMR measurements of the amount of the first and second silicon containing compound bonded to the dual silane modified colloidal silica particles. First and second control compositions were also evaluated. The first control composition included identical colloidal silica particles that were not modified with either the first or second silicon containing compounds. The second control composition included identical colloidal silica particles that were modified with the first silicon containing compound (bis(trimethoxysilylpropyl)amine at a theoretical modification level of 10%) but not the second silicon containing compound. Table 2A lists the pH, conductivity, particle size, zeta potential, and IEP. Table 2B lists the Sear's number and the total carbon. Table 2C lists the measured (via NMR) and theoretical amounts of the first and second compounds.

The particle sizes were measured using the Zetasizer® (available from Malvern® instruments). The zeta potential was measured at pH 3.5 using the Colloidal Dynamics Zetaprobe Analyzer®. No Smoluchowski correction was applied. The procedure for measuring the IEP was as described above using a KOH base titration and Zetaprobe Analyzer® zeta potential measurements. The Sear's number was determined via a Sear's titration using the procedure described above.

The total carbon was determined via combusting dried particle samples and measuring the total carbon dioxide generated as also described above. The dried samples were obtained by three successive centrifugation/wash cycles and then oven drying overnight at 60 degrees C under vacuum. The total carbon is reported in Table 2B as a percent of the total mass (percent carbon) and as a number of carbon atoms per nm² of BET surface area. A theoretical number of carbon atoms per nm² was computed based on the BET surface area and the theoretical modification levels listed in Example 1.

The procedure for making the NMR measurements was as follows. Dried samples were obtained as described above for the total carbon measurements. The dried particles were dissolved in concentrated KOH (pH~14) to dissolve the colloidal silica particles and release the surface modifying compounds into solution. The digested solution was then prepared for ¹H NMR analysis. The proton signals of the surface modifying compounds were analyzed to determine the nature and amount of surface modification. The amount of each compound was determined via the corresponding peak areas and is reported in Table 2C in units of μmol/m² (BET surface area) of each silane compound. A theoretical amount of each silane compound in the same units was computed based on the BET surface area and the theoretical modification levels listed in Example 1.

TABLE 2A

| | | | Particle | Zeta | |
|---|---|---|---|---|---|
| | | Conductivity | Size | Potential | Isoelectric |
| Composition | pH | (μS/cm) | (nm) | (mV) | Point |
| Control 1 | 7.2 | | 120 | 14 | 4.5 |
| Control 2 | 2.8 | 820 | 124 | 89 | 7.4 |
| 1A | 2.8 | 1989 | 121 | 98 | 8.2 |
| 1B | 2.8 | 1763 | 122 | 97 | 8.6 |
| 1C | 2.8 | 1492 | 123 | 85 | 8.6 |

TABLE 2B

| | Sear's | Carbon | Carbon | Theoretical Carbon |
|---|---|---|---|---|
| Composition | Number | (%) | atoms/nm² | (atoms/nm²) |
| Control 1 | 3.2 | 0.06 | 0.8 | |
| Control 2 | 2.3 | 0.16 | 2.2 | 1.8 |
| 1A | 1.4 | 0.8 | 11.3 | 11.6 |
| 1B | 1.3 | 1.1 | 15.9 | 21.1 |
| 1C | 0.9 | 2.0 | 27.7 | 40.1 |

TABLE 2C

| | First Silane | | Second Silane | |
|---|---|---|---|---|
| | NMR | Theoretical | NMR | Theoretical |
| Composition | (μmol/m²) | (μmol/m²) | (μmol/m²) | (μmol/m²) |
| Control 1 | | | | |
| Control 2 | 0.4 | 0.4 | | |
| 1A | 0.5 | 0.8 | 1.6 | 1.9 |
| 1B | 0.5 | 0.8 | 3.2 | 3.7 |
| 1C | 0.5 | 0.8 | 4.1 | 7.5 |

As is apparent from the results set forth in Tables 2A, 2B, and 2C, the particle size remained unchanged with increasing modification, the dual silane modified colloidal silica particles had high positive zeta potentials and an IEP of greater than 8. The Sear's number decreased with increasing modification level and the total carbon and measured modification levels increased with increasing theoretical modification level. The measured modification levels were nearly identical to the theoretical modification levels at the lower modification levels.

### Example 3

Five polishing compositions were prepared using the corresponding particle dispersions prepared above in Example 1. Each polishing composition included 0.0445 wt. % malonic acid, 0.0206 wt. % ferric nitrate nonahydrate, 13 ppm by weight epsilon poly-L-lysine, 17 ppm by weight Proxel AQ preservative, 3.0 wt. % hydrogen peroxide and 0.3 wt. % of the colloidal silica particles. The pH of each composition was adjusted to 2.7 using potassium hydroxide. The colloidal silica particles in compositions 3A, 3B, and 3C were identical to those in corresponding compositions 1A, 1B, and 1C. The colloidal silica particles in the Control compositions were identical to those in the control compositions in Example 2.

The CMP performance of each composition was evaluated using a Reflexion® CMP polishing tool (Applied Materials) with an E6088 polishing pad (Entegris) and in-situ conditioning using a Saesol C1 conditioner at 4.5 lbs. Tungsten and TEOS polishing rates were obtained by polishing 300 mm blanket tungsten and TEOS wafers at a downforce of 3.0 psi, a platen speed of 100 rpm, a head speed of 101 rpm, and a slurry flow rate was 200 mL/min. Blanket wafer polishing rates (removal rates) are shown in Table 3A. Patterned wafer polishing performance was evaluated by polishing 300 mm 2kÅ PureWafer tungsten patterned wafers at the same conditions. Each patterned wafer was polished to optical end-point plus 30 percent over polish. Patterned wafer performance was evaluated using atomic force microscope (AFM) profilometer measurements across 1×1 and 3×1 micron line features. The patterned wafer polishing data is shown in Table 3B.

TABLE 3A

| | Theoretical | | Blanket | |
|---|---|---|---|---|
| | Modification | Blanket W | TEOS | |
| | Levels | Rate | Rate | W:TEOS |
| Composition | (%, %) | (Å/min) | (Å/min) | Selectivity |
| Control 1 | 0, 0 | 3006 | 377 | 8 |
| Control 2 | 10, 0 | 3499 | 33 | 106 |
| 3A | 22, 25 | 3857 | 34 | 113 |
| 3B | 22, 50 | 3705 | 24 | 154 |
| 3C | 22, 100 | 2612 | 24 | 109 |

TABLE 3B

| | Patterned | Patterned | Dishing | Erosion | Dishing | Erosion |
|---|---|---|---|---|---|---|
| Compo- | W Rate | Oxide Loss | 1 × 1 | 1 × 1 | 3 × 1 | 3 × 1 |
| sition | (Å/min) | (Å) | (Å) | (Å) | (Å) | (Å) |
| Con- | 2853 | 31 | 284 | 126 | 439 | 393 |
| trol 1 | | | | | | |
| Con- | 3499 | 47 | 62 | 276 | 133 | 583 |
| trol 2 | | | | | | |
| 3A | 3857 | 33 | 68 | 236 | 158 | 567 |
| 3B | 3705 | 22 | 43 | 18 | 79 | 134 |
| 3C | 2612 | 14 | 39 | 27 | 41 | 87 |

As is apparent from the results set forth in Tables 3A and 3B, the compositions including the dual silane modified colloidal silica particles exhibited significantly improved erosion and dishing, particularly compositions 3B and 3C. A modest improvement in the tungsten removal rate was observed in compositions 3A and 3B.

### Example 4

Four dual silane modified colloidal silica dispersions were prepared using a procedure similar to that described above in Example 1. The colloidal silica particles and the first silicon containing compound were the same as used in Example 1. A single dose of the first silicon containing compound (no second dose) was used to provide the colloidal silica particles with a theoretical modification level of 15 percent. Four distinct second silicon containing compounds were evaluated at a theoretical modification level of 50 percent. The second silicon containing compounds were 3-trimethoxysilylpropyl methacrylate (4A), acryloxypropyl trimethoxysilane (4B), acryloxymethyl trimethoxysilane (4C), and 3-methacrylamidopropyl triethoxysilane (4D).

The particle size, zeta potential, IEP, Sear's number, and NMR measured amounts of the first and second silicon containing compounds were measured using the procedures described above in Example 2. Table 4A lists the particle size, zeta potential, and IEP. Table 4B lists theoretical Log D of the second silicon containing compounds (computed using Percepta Software, ACD labs), the measured Sear's number, and the NMR measured amounts of the first and second silicon containing compounds.

TABLE 4A

| | Particle Size | Zeta Potential | Isoelectric |
|---|---|---|---|
| Composition | (nm) | (mV) | Point |
| 4A | 124 | 80 | 8.6 |
| 4B | 122 | 99 | 6.5 |
| 4C | 122 | 99 | 6.6 |
| 4D | 123 | 105 | 8.1 |

TABLE 4B

| | | Sear's | First Silane | Second Silane |
|---|---|---|---|---|
| Composition | LogD | Number | (μmol/m²) | (μmol/m²) |
| 4A | 1.11 | 0.8 | 0.6 | 3.7 |
| 4B | 0.66 | 1.1 | 0.4 | 2.6 |
| 4C | 0.25 | 2 | 0.4 | 2.8 |
| 4D | 0.06 | 2.1 | 0.4 | 1.9 |

As is apparent from the results set forth in Tables 4A and 4B, the Sear's number decreased with increasing Log D of the second silicon containing compound and the amount of first and second silicon containing compounds increased with increasing Log D of the second silicon containing compound.

### Example 5

Four polishing compositions were prepared using the corresponding particle dispersions described above in Example 4. Each polishing composition included 0.0445 wt. % malonic acid, 0.0206 wt. % ferric nitrate nonahydrate, 13 ppm by weight epsilon poly-L-lysine, 17 ppm by weight Proxel AQ preservative, 3.0 wt. % hydrogen peroxide and 0.3 wt. % colloidal silica particles. The pH of each composition was adjusted to 2.7 using potassium hydroxide.

The CMP performance of each composition was evaluated using a Reflexion® CMP polishing tool (Applied Materials) with an E6088 polishing pad (Entegris) and in-situ conditioning using a Saesol C1 conditioner at 4.5 lbs. Tungsten and TEOS polishing rates were obtained by polishing 300 mm blanket tungsten and TEOS wafers at a downforce of 3.0 psi, a platen speed of 100 rpm, a head speed of 101 rpm, and a slurry flow rate was 200 mL/min. Blanket wafer polishing rates (removal rates) are shown in Table 5A. Patterned wafer polishing performance was evaluated by polishing 300 mm 2kÅ Silyb 754 tungsten patterned wafers at the same conditions. Each patterned wafer was polished to optical end-point plus 30 percent overpolish. Patterned wafer performance was evaluated using atomic force microscope (AFM) profilometer measurements across 1×1 and 3×1 micron line features. The patterned wafer polishing data is shown in Table 5B.

TABLE 5A

| | Blanket W | Blanket TEOS | W:TEOS |
|---|---|---|---|
| Composition | Rate (Å/min) | Rate (Å/min) | Selectivity |
| 5A | 3427 | 29 | 118 |
| 5B | 3424 | 37 | 93 |
| 5C | 3771 | 37 | 102 |
| 5D | 3534 | 33 | 107 |

TABLE 5B

| | Patterned | Patterned | Dishing | Erosion | Dishing | Erosion |
|---|---|---|---|---|---|---|
| Compo- | W Rate | Oxide Loss | 1 × 1 | 1 × 1 | 3 × 1 | 3 × 1 |
| sition | (Å/min) | (Å) | (Å) | (Å) | (Å) | (Å) |
| 5A | 3759 | 5 | 75 | 77 | 155 | 365 |
| 5B | 3900 | 17 | 148 | 190 | 235 | 564 |
| 5C | 3622 | 19 | 130 | 282 | 181 | 623 |
| 5D | 3912 | 25 | 113 | 286 | 164 | 631 |

As is readily apparent from the data set forth in Tables 5A and 5B, composition 5A achieved superior erosion and dishing performance. The erosion performance exhibited by composition 5B was better than compositions 5C and 5D on both the 1×1 and the aggressive 3×1 array.

### Example 6

Two dual silane modified colloidal silica dispersions were prepared using a procedure similar to that described above in Example 1. The colloidal silica particles and the first silicon containing compound were the same as used in Example 1. A single dose of the first silicon containing compound (no second dose) was used to provide the colloidal silica particles with a theoretical modification level of 15 percent. Two distinct second silicon containing compounds were evaluated at a theoretical modification level of 50 percent. The second silicon containing compounds were 3-trimethoxysilylpropyl methacrylate (6A) and (isobutyryloxy)trimethoxysilane (6B).

The particle size, zeta potential, IEP, Sear's number, and NMR measured amounts of the first and second silicon containing compounds were measured using the procedures described above in Example 2. Table 6A lists the particle size, zeta potential, and IEP. Table 6B lists the Log D of the second silicon containing compounds (computed using Percepta Software, ACD labs), the measured Sear's number, and the NMR measured amounts of the first and second silicon containing compounds.

TABLE 6A

| | Particle Size | Zeta Potential | Isoelectric |
|---|---|---|---|
| Composition | (nm) | (mV) | Point |
| 6A | 124 | 80 | 8.6 |
| 6B | 130 | 81 | 8.9 |

TABLE 6B

| | | | First | Second |
|---|---|---|---|---|
| | | Sear's | Compound | Compound |
| Composition | LogD | Number | (μmol/m²) | (μmol/m²) |
| 6A | 1.11 | 0.8 | 0.6 | 3.7 |
| 6B | 1.03 | 0.8 | 0.6 | 3.6 |

As is readily apparent from the data set forth in Tables 6A and 6B, the dual modified colloidal silicas in compositions 6A and 6B exhibited very high isoelectric points (>8.5) and low Sear's numbers (<1). They also exhibited similar amounts of the first and second silicon containing compounds.

### Example 7

Two polishing compositions were prepared using the corresponding particle dispersions described above in Example 6. Each polishing composition included 0.0445 wt. % malonic acid, 0.0206 wt. % ferric nitrate nonahydrate, 13 ppm by weight epsilon poly-L-lysine, 17 ppm by weight Proxel AQ preservative, 3.0 wt. % hydrogen peroxide and 0.3 wt. % colloidal silica particles. The pH of each composition was adjusted to 2.7 using potassium hydroxide.

The CMP performance of each composition was evaluated using a Reflexion® CMP polishing tool (Applied Materials) with an E6088 polishing pad (Entegris) and in-situ conditioning using a Saesol C1 conditioner at 4.5 lbs. Tungsten and TEOS polishing rates were obtained by polishing 300 mm blanket tungsten and TEOS wafers at a downforce of 3.0 psi, a platen speed of 100 rpm, a head speed of 101 rpm, and a slurry flow rate was 200 mL/min. Blanket wafer polishing rates (removal rates) are shown in Table 7A. Patterned wafer polishing performance was evaluated by polishing 300 mm 2kÅ PureWafer tungsten patterned wafers at the same conditions. Each patterned wafer was polished to optical end-point plus 30 percent overpolish. Patterned wafer performance was evaluated using atomic force microscope (AFM) profilometer measurements across 1×1 and 3×1 micron line features. The patterned wafer polishing data is shown in Table 7B.

TABLE 7A

| | Blanket W | Blanket TEOS | W:TEOS |
|---|---|---|---|
| Composition | Rate (Å/min) | Rate (Å/min) | Selectivity |
| 7A | 3135 | 31 | 101 |
| 7B | 3233 | 33 | 98 |

TABLE 7B

| | Patterned | Patterned | Dishing | Erosion | Dishing | Erosion |
|---|---|---|---|---|---|---|
| Compo- | W Rate | Oxide Loss | 1 × 1 | 1 × 1 | 3 × 1 | 3 × 1 |
| sition | (Å/min) | (Å) | (Å) | (Å) | (Å) | (Å) |
| 7A | 2957 | 22 | 70 | 70 | 112 | 263 |
| 7B | 2876 | 23 | 58 | 72 | 109 | 203 |

As is readily apparent from the results set forth in Tables 7A and 7B, both compositions exhibited outstanding dishing and erosion performance.

### Example 8

Three dual silane modified colloidal silica dispersions were prepared using the procedure described above in Examples 4 and 6. The colloidal silica particles were similar to those used in Examples 1, 4, and 6, but had a nominal particle size of about 100 nm. The first and second silicon containing compounds were the same as used in Example 1. The theoretical modification levels of the second silicon containing compound are listed in Table 8. A control composition included the same colloidal silica particle having a theoretical modification level of 15 percent of the first silicon containing compound (and no second silicon containing compound).

The particle size, Sear's number, and NMR measured amounts of the first and second silicon containing compounds were measured using the procedures described above in Example 2. Table 8 lists these measurement values along with the theoretical modification level of the second silicon containing compound.

TABLE 8

| | Modifi- | Particle | | First | Second |
|---|---|---|---|---|---|
| | cation | Size | Sear's | Compound | Compound |
| Composition | (%) | (nm) | Number | (μmol/m²) | (μmol/m²) |
| Control | 0 | 99 | 1.8 | 0.6 | 0 |
| 8A | 40 | 99 | 0.9 | 0.5 | 2.8 |
| 8B | 50 | 101 | 0.9 | 0.5 | 3.7 |
| 8C | 60 | 100 | 0.8 | 0.5 | 4.3 |

As is readily apparent from the data set forth in Table 8, each of the dual silane modified colloidal silica compositions has a low Sear's number (<1). The amount of the second silicon containing compound on the colloidal silica compositions increased with the increasing theoretical modification level.

### Example 9

Four polishing compositions were prepared using the corresponding particle dispersions described above in Example 8. Each polishing composition included 0.0445 wt. % malonic acid, 0.0206 wt. % ferric nitrate nonahydrate, 13 ppm by weight epsilon poly-L-lysine, 17 ppm by weight Proxel AQ preservative, 3.0 wt. % hydrogen peroxide and 0.3 wt. % colloidal silica particles. The pH of each composition was adjusted to 2.7 using potassium hydroxide. The CMP performance of each composition was evaluated using a Reflexion® CMP polishing tool (Applied Materials) with an E6088 polishing pad (Entegris) and in-situ conditioning using a Saesol C1 conditioner at 4.5 lbs. Patterned wafer polishing performance was evaluated by polishing 300 mm 2kÅ Silyb 754 tungsten patterned wafers at a downforce of 3.0 psi, a platen speed of 100 rpm, a head speed of 101 rpm, and a slurry flow rate was 200 mL/min. Each patterned wafer was polished to optical end-point plus 30 percent overpolish. Patterned wafer performance was evaluated using atomic force microscope (AFM) profilometer measurements across 1×1 and 3×1 micron line features. The patterned wafer polishing data is shown in Table 9.

TABLE 9

| | Patterned | Patterned | Dishing | Erosion | Dishing | Erosion |
|---|---|---|---|---|---|---|
| Compo- | W Rate | Oxide Loss | 1 × 1 | 1 × 1 | 3 × 1 | 3 × 1 |
| sition | (Å/min) | (Å) | (Å) | (Å) | (Å) | (Å) |
| Control | 3401 | 55 | 119 | 444 | 85 | 784 |
| 9A | 3173 | 34 | 129 | 171 | 206 | 617 |
| 9B | 3004 | 24 | 123 | 110 | 221 | 389 |
| 9C | 2985 | 21 | 114 | 80 | 196 | 316 |

As is readily apparent from the results set forth in Table 9, polishing compositions 9A, 9B, and 9C (particularly compositions 9B and 9C) exhibited significantly improved erosion performance as compared to the Control.

### Example 10

Six polishing compositions 10A, 10B, 10C, 10D, 10E, and 10F and a Control polishing composition were prepared using corresponding particle dispersions 4A, 4A, 4B, 4C, 4D, and 6B described above in Examples 4 and 6 and Control 2 described above in Example 2. The Control composition and polishing composition 10A included 0.08 wt. % malonic acid, 0.040 wt. % ferric nitrate nonahydrate, 0.0134 wt. % polyDADMAC, and 0.9 wt. % of the colloidal silica particles. Compositions 10B, 10C, 10D, 10E, and 10F included 0.12 wt. % malonic acid, 0.060 wt. % ferric nitrate nonahydrate, 0.020 wt. % polyDADMAC, 5.5 ppm by weight Proxel AQ preservative, and 0.45 wt. % of the dual silane modified colloidal silica particles. The pH of each composition was adjusted to 2.6 using potassium hydroxide.

The CMP performance of each composition was evaluated using a Logitech 2 benchtop polishing machine with an E6088 polishing pad (Entegris) and in-situ conditioning using a 3M A122 conditioner. Blanket wafer polishing rates were obtained by polishing blanket TEOS, Spin on Carbon, and/or Tier 1 Hard Carbon wafers at a downforce of 3.0 psi (20.6 kPa), a platen speed of 93 rpm, a head speed of 87 rpm, and a slurry flow rate of 50 mL/min for 60 seconds. The results are set forth in Table 10.

TABLE 10

| | | Spin-on- | |
|---|---|---|---|
| | TEOS Rate | Carbon Rate | Tier 1 Rate |
| Composition | (Å/min) | (Å/min) | (Å/min) |
| Control | 8 | 2183 | |
| 10A | 0 | 5659 | |
| 10B | 0 | 5406 | 20 |
| 10C | 17 | 2535 | 10 |
| 10D | 18 | 2644 | 13 |
| 10E | 15 | 2259 | 12 |
| 10F | 18 | 5993 | 20 |

As is readily apparent from Table 10, polishing compositions 10A, 10B, and 10F achieved superior polishing rates on both the spin on carbon and Tier 1 Hard carbon films.

It will be understood that the recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A chemical mechanical polishing composition comprising:
a liquid carrier;
colloidal silica particles dispersed in the liquid carrier;
an aminosilane compound covalently bonded to an outer surface of the colloidal silica particles such that the colloidal silica particles have a positive charge in the polishing composition; and
a nonionic silane compound covalently bonded to the outer surface of the colloidal silica particles;
wherein a molar ratio of the nonionic silane compound to the aminosilane compound covalently bonded to the surface of the colloidal silica particles is greater than about 4:1.

2. The composition of claim 1, wherein the nonionic silane compound has a theoretical distribution coefficient logarithm (Log D) that is in a range from about 0.6.

3. The composition of claim 1, wherein the nonionic silane compound has a theoretical distribution coefficient logarithm (Log D) that is in a range from about 0.6 to about 1.6.

4. The composition of claim 1, wherein the nonionic silane comprises an acrylate silane or a methacrylate silane.

5. The composition of claim 1, wherein the colloidal silica particles have Sears's number of less than about 1.6.

6. The composition o of claim 1, wherein the colloidal silica particles comprise at least about 10 carbon atoms per nm² of BET surface area.

7. The composition of claim 1, wherein the colloidal silica particles comprise at least about 1.5 μmol of the nonionic silane compound per m² of BET surface area.

8. The composition of claim 1, wherein:
the aminosilane compound comprises a multi-podal aminosilane compound; or
the aminosilane compound comprises a first mono-podal aminosilane compound and a second multi-podal aminosilane compound.

9. The composition of claim 1, wherein the colloidal silica particles comprise at least about 0.2 μmol of the aminosilane compound per m² of BET surface area.

10. The composition of claim 1, wherein the colloidal silica particles have a zeta potential of greater than about 30 mV in the polishing composition.

11. The composition of claim 1, wherein the colloidal silica particles have an average particle size in a range from about 25 nm to about 200 nm.

12. The composition of claim 1, comprising from about 0.01 to about 1 weight percent of the colloidal silica particles at point of use.

13. The composition of claim 1, further comprising a soluble iron containing compound and a stabilizer bound to the soluble iron containing compound.

14. The composition of claim 1, further comprising a cationic polymer or a cationic surfactant.

15. The composition of claim 1, wherein the composition comprises:
from about 0.01 wt. % to about 1 wt. % of the colloidal silica particles at point of use;
from about 1 to about 100 ppm by weight of a cationic polymer or cationic surfactant at point of use; and
an iron containing compound contributing from about 1 ppm to about 100 ppm iron at point of use.

16. The composition of claim 1, wherein:
the colloidal silica particles comprise first and second colloidal silica particles, the first colloidal silica particles having a particle size of greater than 80 nm and the second colloidal silica particles having a particle size in a range from about 30 nm to about 80 nm; and
at least one of the first and second colloidal silica particles comprise the aminosilane compound and the nonionic silane compound covalently bonded to the surface thereof.

17. The composition of claim 1, having a pH of less than about 5.

18. A method of chemical mechanical polishing a substrate, the method comprising:
contacting the substrate with a polishing composition comprising a liquid carrier, colloidal silica particles dispersed in the liquid carrier, an aminosilane compound covalently bonded to an outer surface of the colloidal silica particles such that the colloidal silica particles have a positive charge in the polishing composition, and a nonionic silane compound covalently bonded to the outer surface of the colloidal silica particles, wherein a molar ratio of the nonionic silane compound to the aminosilane compound covalently bonded to the surface of the colloidal silica particles is greater than about 4:1;
moving the polishing composition relative to the substrate; and
abrading the substrate to remove at least a portion of a metal or a dielectric material from the substrate and thereby polish the substrate.

19. The method of claim 18, wherein:
the polishing composition further comprises a soluble iron containing catalyst and a polycarboxylic acid stabilizer bound to the soluble iron containing catalyst; and
the abrading removes at least a portion of a tungsten or a molybdenum metal layer from the substrate.

20. The method of claim 18, wherein:
the polishing composition further comprises a soluble iron containing compound and a stabilizer bound to the soluble iron containing compound; and
the abrading removes at least a portion of a carbon layer from the substrate.
